(19) United States
(12) Patent Application Publication
(10) Pub. No.: US 2009/0218588 A1
(43) Pub. Date: Sep. 3, 2009

(54) CHIP-SCALE PACKAGED LIGHT-EMITTING DEVICES

(76) Inventors: Paul Panaccione, Newburyport, MA (US); Charles W.C. Lin, Yunghe (TW); Chia-Chung Wang, Hsinchu 310 (TW); Cheng-Chung Chen, Taipei 112 (TW)

Correspondence Address: LUMINUS DEVICES , INC.;C/O WOLF, GREENFIELD & SACKS , P.C., 600 ATLANTIC AVENUE, BOSTON, MA, 02210-2206, US

(21) Appl. No.: 12/327,910

(22) Filed: Dec. 4, 2008

Related U.S. Application Data
(60) Provisional application No. 60/992,869, filed on Dec. 6, 2007.

(51) Int. Cl. H01L 33/00; H01L 21/50

(52) U.S. Cl. 257/99; 438/26; 257/E33.066; 257/E21.499

(57) ABSTRACT

Light-emitting devices, and related components, systems, and methods associated therewith are provided. A light-emitting device can comprise a light-emitting die comprising a light-generating region capable of generating light and an emission surface through which generated light is capable of being emitted, and a package layer at least partially disposed over at least a portion of the light-emitting die emission surface, wherein the package layer has an aperture through which light from the light-emitting die is capable of being emitted. The light-emitting device can be a chip-scale packaged device where the device area can be less than 3 times the light-emitting die emission surface area and/or the device thickness can be less than 2 times the light-emitting die thickness.

### RELATED APPLICATIONS

This application claims priority to U.S. Provisional Patent Application Ser. No. 60/992,869, filed Dec. 6, 2007, which is incorporated herein by reference.

### FIELD

The present embodiments are drawn generally towards light emitting devices, and more specifically to chip-scale packaged light-emitting devices.

### BACKGROUND

A light-emitting diode (LED) can provide light in a more efficient manner than an incandescent light source and/or a fluorescent light source. The relatively high power efficiency associated with LEDs has created an interest in using LEDs to displace conventional light sources in a variety of lighting applications. For example, in some instances LEDs are being used as traffic lights and to illuminate cell phone keypads and displays.

Typically, an LED is formed of multiple layers, with at least some of the layers being formed of different materials. In general, the materials and thicknesses selected for the layers influence the wavelength(s) of light emitted by the LED. In addition, the chemical composition of the layers can be selected to promote isolation of injected electrical charge carriers into regions (commonly including quantum wells) for relatively efficient conversion to light. Generally, the layers on one side of the junction where a quantum well is grown are doped with donor atoms that result in high electron concentration (such layers are commonly referred to as n-type layers), and the layers on the opposite side are doped with acceptor atoms that result in a relatively high hole concentration (such layers are commonly referred to as p-type layers).

LEDs also generally include contact structures (also referred to as electrical contact structures or electrodes), which are conductive features of the device that may be electrically connected to an electrical driver circuit. The driver can provide electrical current to the device via the contact structures, e.g., the contact structures can deliver current along the lengths of structures to the surface of the device within which light may be generated.

### BRIEF DESCRIPTION OF DRAWINGS

FIG. 1A shows a cross-section of a light-emitting device according to an embodiment.

FIG. 1B shows a top view of the light-emitting device of FIG. 1A.

FIG. 1C shows a bottom view of the light-emitting device shown in FIG. 1A.

FIGS. 2A-2F illustrate cross-sections of intermediate structures used during a method according to an embodiment.

FIGS. 3A-3E illustrate cross-sections of intermediate structures used during a method according to an embodiment.

FIG. 4 illustrates a process for attaching a light-emitting device to a substrate according to an embodiment.

FIG. 5 illustrates a light-emitting device attached to a substrate according to an embodiment.

FIG. 6 illustrates a light-emitting device attached to a substrate according to an embodiment.

FIG. 7 illustrates a light-emitting device attached to a substrate according to an embodiment.

FIG. 8 illustrates a light-emitting device attached to a substrate according to an embodiment.

FIG. 9 illustrates a light-emitting device after substrate removal according to an embodiment.

FIG. 10 illustrates a packaged light-emitting device according to an embodiment.

FIG. 11 illustrates a light-emitting diode according to an embodiment.

### SUMMARY

Light-emitting devices, and related components, systems, and methods associated therewith are provided.

In one aspect, a light-emitting device comprises a light-emitting die comprising a light-generating region capable of generating light and an emission surface through which generated light is capable of being emitted, and a package layer at least partially disposed over at least a portion of the light-emitting die emission surface, wherein the package layer has an aperture through which light from the light-emitting die is capable of being emitted.

In one aspect, a light-emitting device comprises a light-emitting die comprises a light-generating region capable of generating light and an emission surface through which generated light is capable of being emitted, and a package that houses the light-emitting die, wherein the light-emitting die is at least partially embedded in the package, and wherein the device area is less than 3 times the light-emitting die emission surface area.

In one aspect, a light-emitting device comprises a light-emitting die comprises a light-generating region capable of generating light and an emission surface through which generated light is capable of being emitted, and a package that houses the light-emitting die, wherein the light-emitting die is at least partially embedded in the package, and wherein the device thickness is less than 2 times the light-emitting die thickness.

In one aspect, a light-emitting device comprises a light-emitting die comprising a light-generating region capable of generating light and an emission surface through which generated light is capable of being emitted, and a package that houses the light-emitting die, the package having a top surface less than 100 micrometers from the light-emitting die emission surface.

In one aspect, a method of making a light-emitting device is provided. The method comprises providing a light-emitting die comprising a light-generating region capable of generating light and an emission surface through which generated light is capable of being emitted, and providing a package layer at least partially disposed over at least a portion of the light-emitting die emission surface, wherein the package layer has an aperture through which light from the light-emitting die is capable of being emitted.

Other aspects, embodiments and features of the invention will become apparent from the following detailed description of the invention when considered in conjunction with the accompanying figures. The accompanying figures are schematic and are not intended to be drawn to scale. In the figures, each identical or substantially similar component that is illustrated in various figures is represented by a single numeral or notation.

For purposes of clarity, not every component is labeled in every figure. Nor is every component of each embodiment of the invention shown where illustration is not necessary to allow those of ordinary skill in the art to understand the invention. All patent applications and patents incorporated herein by reference are incorporated by reference in their entirety. In case of conflict, the present specification, including definitions, will control.

### DETAILED DESCRIPTION

Some embodiments presented herein describe chip-scale packaged light-emitting devices comprising a light-emitting die including a light-generating region capable of generating light, where the light-emitting die includes an emission surface through which generated light is capable of being emitted. In some embodiments, a package houses the light-emitting die. The light-emitting die can be at least partially embedded in the package. The package can include a package layer at least partially disposed over at least a portion of the light-emitting die emission surface. The package layer may include an aperture through which light from the light-emitting die is capable of being emitted. The package can have a top surface less than about 100 micrometers from the light-emitting die emission surface. In some embodiments, the chip-scale packaged device has a device area less than 3 times the light-emitting die emission surface area. In some embodiments, the chip-scale packaged device thickness is less than 2 times the light-emitting die thickness.

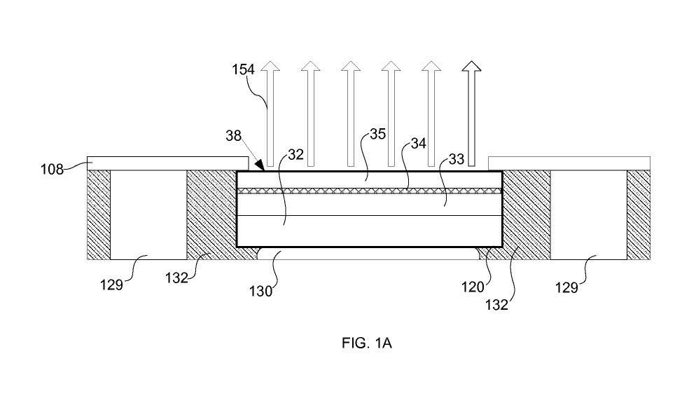

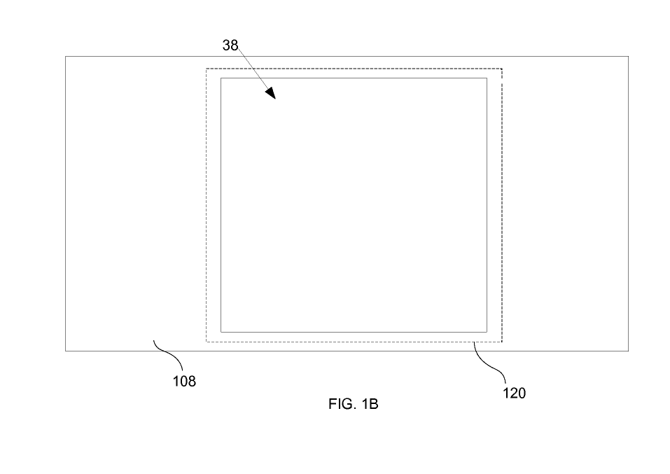

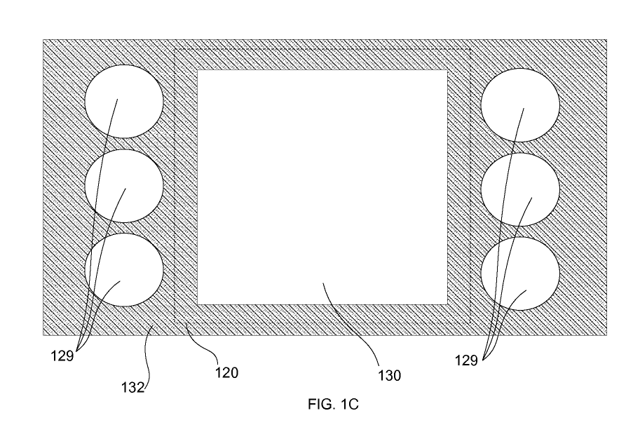

FIG. 1A illustrates a cross-section view of a light-emitting device including a light-emitting die 120. Light-emitting die 120 may be a light-emitting diode die or laser diode die. Light-emitting die 120 can include semiconductor layers 33, 34, and 35. Layer 34 may be a light-generating region, also referred to as an active region which can include one or more quantum wells. Semiconductor layer 33 can be a semiconductor of a first conductivity type (e.g., n-type or p-type) and semiconductor layer 32 can be a semiconductor of a second conductivity type (e.g., p-type or n-type), thereby forming a p-n junction where the light-generating region can be disposed between the n-type and p-type regions. Semiconductor layer 33 can be attached to a layer 32 which can include reflective layer(s) (e.g., a metal layer stack, a dielectric or semiconductor multilayer mirror) and a supporting submount layer (e.g., one or more metal layers, such as a copper or copper-tungsten submount). The reflective layer(s) can be in contact with the semiconductor layer 33. The submount and/or any reflective layers disposed under semiconductor layer 33 can be electrically conductive, thereby providing for electrical contact to the semiconductor layer 33.

Light-emitting die 120 include an emission surface 38 through which light generated by the light-generating region 34 can be emitted, as represented by arrows 154.

Light-emitting die 120 may be formed by transferring semiconductor layers onto a supporting submount, for example, by using a grinding, etching, and/or laser liftoff process. Laser liftoff processes are disclosed, for example, in U.S. Pat. Nos. 6,420,242 and 6,071,795, which are hereby incorporated by reference in their entirety. It should be appreciated that other methods of forming the light-emitting die 120 are possible, as the embodiments presented herein are not limited in this respect.

In some embodiments, the light-emitting die can be a large-area die have an emission area greater than or equal to about 1 mm². In some embodiments, the light-emitting die emission area can be greater than 3 mm². In some embodiments, the light-emitting die emission area can be greater than or equal to 5 mm². In some embodiments, the light-emitting die emission area can be greater than or equal to 10 mm². A large-area light-emitting die can facilitate the packaging of such dies as a chip-scale packaged light-emitting device, such as the packaged light-emitting devices described herein. Extraction of light from large-area light-emitting dies can be facilitated by the presence of one or more light extraction features. In some embodiments, the one or more light extraction features comprise a roughed surface (e.g., a rough emission surface). In some embodiments, the one or more light extraction features comprise a patterned surface (e.g., a patterned emission surface), as described further below in detail.

A package can house light-emitting die 120. The light-emitting die can be at least partially embedded in the package. As illustrated in the embodiment shown in FIG. 1A, the edges of the light-emitting die 120 can be surrounded by a filler material 132 that can form part of the package. Filler material 132 can be an electrically insulating material (e.g., an epoxy). Filler material 132 can be thermally conductive. Filler material can be optically non-transparent (e.g., non-transparent epoxy, such as black epoxy) or optically transparent (e.g., transparent epoxy).

The package can include a package layer 108 at least partially disposed over at least a portion of the light-emitting die 120 emission surface 38. Package layer 108 can include an aperture through which light from the light-emitting die 120 is capable of being emitted. FIG. 1B illustrates a top-view of the light-emitting device of FIG. 1A. The figure shows a top-view of package layer 108 and the aperture through which light emitted via emission surface 38 of light-emitting die 120 can be transmitted. The perimeter of the light-emitted die 120 is outlined by a dashed line and can be disposed under package layer 108. In some embodiments, the aperture of package layer 108 is rectangular, square, circular, elliptical, triangular, or hexagonal. In some embodiments, the perimeter of the light-emitting die 120 has a different shape than the aperture of package layer 108. For example, the perimeter of light-emitting die 120 has a rectangular or square shape and the aperture of package layer 108 does not have a rectangular or square shape (e.g., circular, elliptical, triangular, or hexagonal).

In some embodiments, at least a portion (e.g., some or all) of the package layer 108 can be disposed over a perimeter of the light-emitting die 120 emission surface 38. An optically transmissive material may be disposed in and/or over at least a portion (e.g., some or all) of the aperture formed by the package layer. The optically transmissive material may be a window that can serve to protect the surface of the light-emitting die 120. Alternatively, in some embodiments, the packaged light-emitting device can be free of a window.

Package layer 108 can include an electrically conductive material, such as one or more metals and/or metal alloys (e.g., nickel, copper, gold, or combinations thereof) that can form an electrical connection with the light-emitting die 120. Package layer 108 can include a multi-layer stack of one or more metals and/or metal alloys. In some embodiments, the electrically conductive material of package layer 108 can serve as part or all of a first electrical contact path to the light-emitting die 120. The first contact path to the can be established via a top surface connection to light-emitting die 120. The light-emitting die 120 can include an electrical bond pad (not shown in FIG. 1A) disposed over the emission surface 38, and the electrically conductive material of package layer 108 can provide for the electrical connection with the electrical bond pad.

A backside of the light-emitting die 120, such as the backside of layer 32, can serve as part or all of a second electrical contact path to the light-emitting die 120. As previously described, the light-emitting die 120 can include a p-type side and an n-type side, and the first electrical contact path can connect to the n-type side of the light-emitting die 120, and the second electrical contact path can connect to the p-type side of the light-emitting die 120. Alternatively, the first electrical contact path can connect to the p-type side of the light-emitting die, and the second electrical contact path can connect to the n-type side of the light-emitting die 120.

In some embodiments, the light-emitting device can include an electrically conductive path 129 from the electrically conductive material of package layer 108 to a backside of the device. In some embodiments, the electrically conductive path 129 to the device backside can include one or more solder balls, metal spheres or columns, leads, other suitable electrically conductive structures. Electrically conductive path 129 may be in contact with package layer 108 and partially exposed on the backside of the light-emitting device, as illustrated in the cross-section view of FIG. 1A.

The light-emitting device may include one or more materials disposed between the electrically conductive path 129 and the light-emitting die 120. For example, filler material 132 can fill part or all of the space between electrically conductive path 129 and the light-emitting die 120. The filler material can be electrically insulating, and thus can provide for electrical isolation between electrically conductive path 129 and the edge of the light-emitting die 120.

The backside of the light-emitting die 120 may be at least partially covered by one or more electrically conductive materials, such as one or more metals. In some embodiments, the backside of the light-emitting die 120 is at least partially covered by solder 130. The solder can cover substantially all or a portion of the light-emitting die 120 backside. Such a configuration can facilitate the attachment (e.g., soldering) of the packaged light-emitting device to another structure, such as a printed circuit board (e.g., a metal core-board) or a heat sink. In some embodiments, the package layer 108 and solder 130 on the light-emitting die 120 backside can have a combined thickness of less than about 250 micrometers (e.g., less than about 200 micrometers, less than about 150 micrometers, less than about 100 micrometers). In some embodiments, the package layer 108 and solder 130 on the light-emitting die 120 backside can have a combined thickness in the range from about 50 micrometers to about 150 micrometers. An exposed die or backside or die backside having a thin layer of material (e.g., a thin layer of solder) can facilitate the removal of heat can directly from the die.

FIG. 1C illustrates a bottom view of the light-emitting device shown in FIG. 1A. One or more electrically conductive paths 129 can be present on one or more edges of the light-emitting die 120. For example, electrically conductive paths 129 may be present on two sides of the light-emitting die 120, as shown in the FIG. 1C. Alternatively, electrically conductive paths 129 may be present on all sides of the light-emitting die 120. Solder 130 can cover part or the entire backside of the light-emitting die 120.

In some embodiments, a light-emitting device, such as the device illustrated in FIGS. 1A-1C, can be a chip-scale packaged light-emitting device having a small device thickness. A small device thickness can facilitate the extraction of heat generated by the light-emitting die. In some embodiments, the light-emitting device comprises a light-emitting die comprising a light-generating region capable of generating light and an emission surface through which generated light is capable of being emitted. A package can house the light-emitting die, wherein the light-emitting die is at least partially embedded in the package. The device thickness can be less than about 2 times the light-emitting die thickness. The device thickness can be less than about 2 times the light-emitting die thickness. The device thickness can be less than about 1.5 times the light-emitting die thickness. The device thickness can be less than about 1.3 times the light-emitting die thickness. The device thickness can be less than about 500 micrometers. The light-emitting die thickness can be less than about 250 micrometers. In some embodiments, the device thickness can be about 500 micrometers or less and the light-emitting die thickness can be about 250 micrometers or less.

In some embodiments, a light-emitting device, such as the device illustrated in FIGS. 1A-1C, can be a chip-scale packaged light-emitting device having a small device area (e.g., package and die area). In some embodiments, the light-emitting device comprises a light-emitting die comprising a light-generating region capable of generating light and an emission surface through which generated light is capable of being emitted. A package can house the light-emitting die, wherein the light-emitting die can be at least partially (e.g., part or all) embedded in the package. The device area can be less than about 3 times the light-emitting die emission surface area. The device area can be less than about 3 times the light-emitting die emission surface area. The device area can be less than about 2 times the light-emitting die emission surface area. The device area can be less than about 1.5 times the light-emitting die emission surface area.

In some embodiments, a light-emitting device, such as the device illustrated in FIGS. 1A-1C, can have a top package layer in close proximity with the emission surface of the light-emitting die. In some embodiments, a package can house the light-emitting die, where the package can have a top surface less than about 100 micrometers from the light-emitting die emission surface. The top surface of the package layer can be less than about 100 micrometers from the light emission surface of the die. The top surface of the package layer can be less than about 75 micrometers from the light emission surface of the die. The top surface of the package layer can be less more than about 50 micrometers from the light emission surface of the die. Such configurations can facilitate the placement of optical components (e.g., len, light guide, etc.) over the emission surface of the light-emitting die, whereby the distance between the optical component and the emission surface is precisely controlled. For example, the optical component can be placed in contact with the package layer 108 of the device shown in FIG. 1A.

Light-emitting devices described herein can be formed using one or more methods presented herein. In one embodiment, the method of making a light-emitting device can include providing a light-emitting die comprising a light-generating region capable of generating light and an emission surface through which generated light is capable of being emitted, and providing a package layer at least partially disposed over at least a portion of the light-emitting die emission surface, wherein the package layer has an aperture through which light from the light-emitting die is capable of being emitted. In some embodiments, a substrate structure can be formed and a light-emitting die can be attached to the substrate structure. Subsequent processing may follow, as described below.

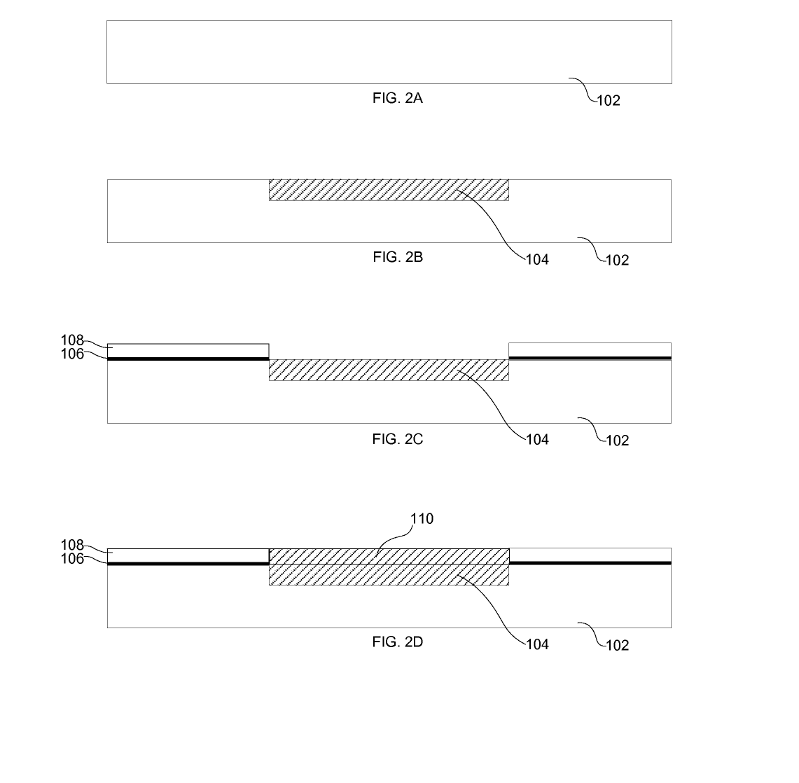

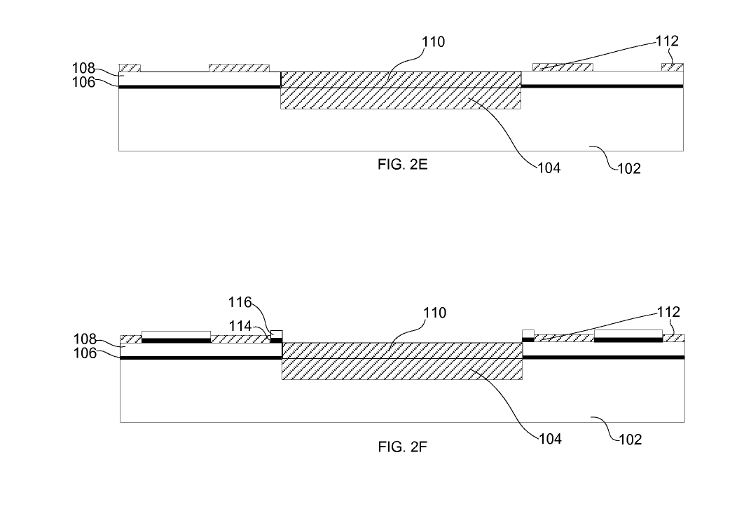

FIGS. 2A-2F illustrate cross-section views of intermediate structures that can be present during the formation of a substrate structure using a first method. The method can include providing a starting substrate 102, as illustrated in FIG. 2A. Starting substrate 102 can be a metal sheet, for example a copper sheet. In some embodiments, the metal sheet has a thickness of less than about 300 micrometers (e.g., less than 200 micrometers, less than 150 micrometers). A cavity can be formed in the starting substrate 102. The cavity can be filled with a mask material 104, as illustrated in FIG. 2B. Mask material 104 can include a solder mask material known to those of ordinary skill in the art. A printing process, for example screen printing, can be used to fill the cavity with mask material 104. Grinding of the mask material 104 may be used to provide for a flush surface of mask material 104 with substrate 102.

Plating can then be used to form package layer 106 and package layer 108 (e.g., metal layers) in unmasked areas of substrate 102, as illustrated in FIG. 2C. In some embodiments, the plating process can include electro-plating, for example, as commonly used in printed circuit board fabrication. Package layer 106 can be a different material (e.g., different metal) than package layer 108. In some embodiments, package layer 108 is formed of the same metal as starting substrate 102. For example, package layer 106 can be a nickel layer. Package layer 108 can be a copper layer. Package layer 106 can serve as a stop layer for further processing that may involve removing (e.g., etching) initial substrate 102.

Mask material 110 can be deposited over mask material 104, as illustrated in FIG. 2D. Mask material 110 and mask material 104 can be formed of the same materials, for example both may be solder mask materials. Mask material 110 may be deposited over mask material 104 using any suitable process known to those in the art, for example, screen printing. Grinding of the mask material 110 may be used to provide for a flush surface of mask material 110 with package layer 108.

Mask material 112 can be deposited over package layer 108, as illustrated in FIG. 2E. Mask material 112 may form a mask that can expose regions of package layer 108. The exposed regions that are not masked may define regions where contact to package layer 108 is desired (e.g., solder bump regions).

Plating may then be used to form layers 114 and 116, as illustrated in FIG. 2F. Layers 114 and 116 may be metal layers, for example layer 114 may be formed of nickel and layer 116 may be formed of gold. Layer 116 may be used as bonding regions, as discussed further below. A nickel layer may serve as a diffusion barrier, whereas a gold layer is useful due to the oxidation resistance of gold.

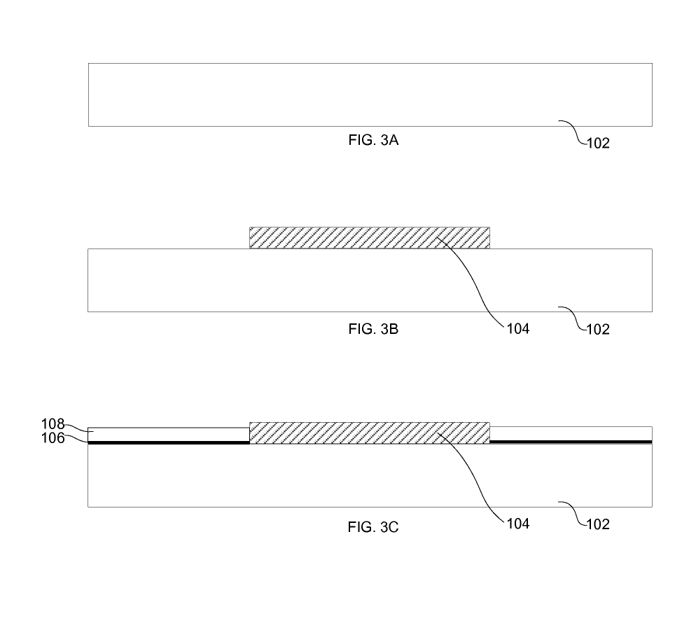

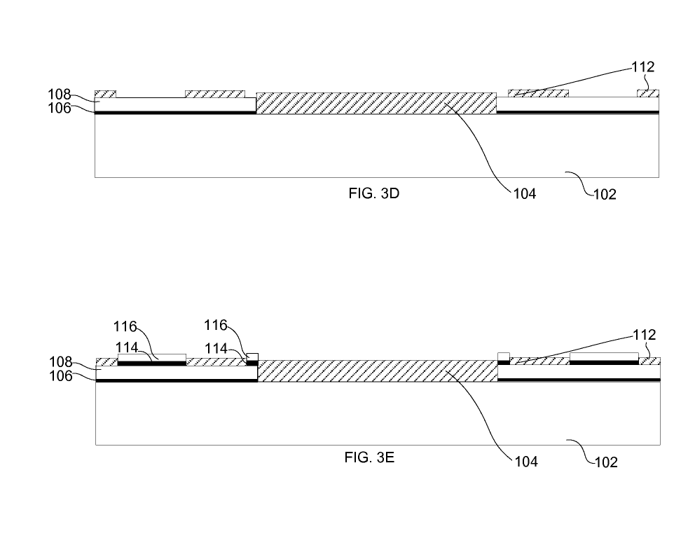

FIGS. 3A-3E illustrate cross-section views of intermediate structures that can be present during the formation of a substrate structure using a different method that that illustrated in FIGS. 2A-2F. The method can include providing a starting substrate 102, as illustrated in FIG. 3A. Starting substrate 102 can be a metal sheet, for example a copper sheet. Mask material 104 can be deposited over starting substrate 102, as illustrated in FIG. 3B. Plating can then be used to form package layer 106 and package layer 108 (e.g., metal layers) in unmasked areas of substrate 102, as illustrated in FIG. 3C. Mask material 112 can be deposited over package layer 108, as illustrated in FIG. 3D. Plating may then be used to form layers 114 and 116, as illustrated in FIG. 3E.

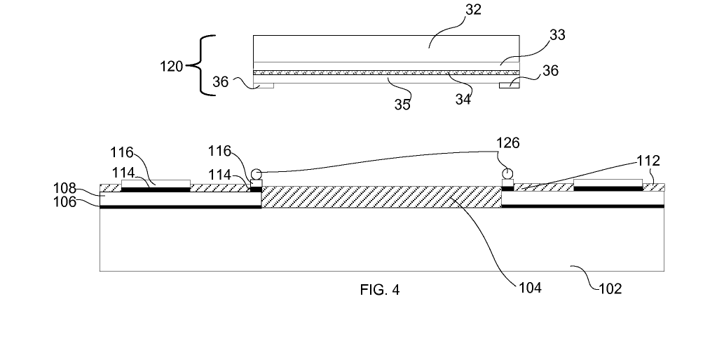

Once the substrate structure (as illustrated in FIG. 2F or 3E) is formed, a package assembly process may be performed which can include a process by which light-emitting die 120 may be attached to the substrate structure, as illustrated in the cross-section view of FIG. 4. Flip-chip bumps 126 (e.g., gold bumps, solder bumps, etc.) may be used to attach the light-emitting die to the substrate structure. A thermo-sonic bonding process may be used to attach light-emitting die 120 bond pads 36 (e.g., gold bond pads) with the bumps 126. The thermo-sonic bonding process may be performed between a temperature of about 100 and about 200 degrees Celsius and may involve the exposure of the bond to ultrasonic sound waves. Optionally thermo-compression bonding without ultrasonic energy may be performed between a temperature of about 200 and about 350 degrees Celsius. For solder bumps, a solder reflow process may be used.

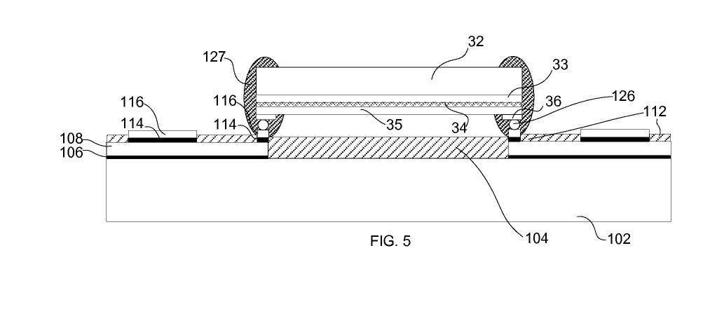

Protective coating 127 may be disposed around the perimeter of the light-emitting die 120, as illustrated in the cross-section view of FIG. 5. Protective coating 127 can provide a seal around the perimeter of the light-emitting die 120 such that any materials involved in subsequent processing does not flow onto the emission surface of the light-emitting die 120. Protective coating 127 may include a high viscosity material. In some embodiments, protective coating 127 may comprise a silicone or an epoxy, such as a high viscosity silicone or epoxy. Protective coating 127 may be dispensed around the periphery of the light-emitting die 120. After dispensing, protective coating 127 may be cured. Curing may be involve heat and/or UV exposure so as to set the epoxy. Protective coating 127 may provide a seal around the periphery of the light-emitting die 120 such that during any subsequent steps no material may contaminate the emission surface of the light-emitting die 120.

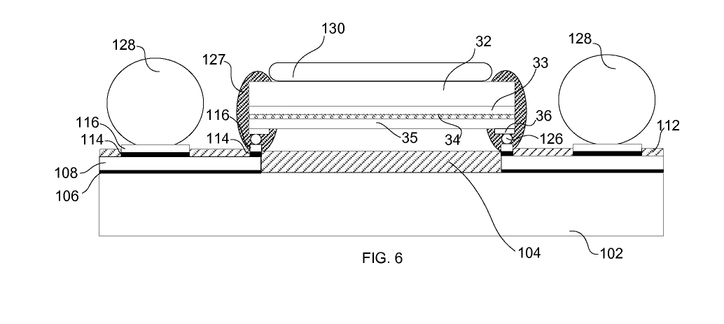

One or more electrically conductive structures 128 may then be placed on pad regions of package layer 116, as illustrated in the cross-section view of FIG. 6. In some embodiments, the electrically conductive structures may include one or more solder balls, metal spheres or columns, and/or leads. In such embodiments, the electrically conductive path between the package layer 108 and the device backside (129 in FIG. 1A) can comprise the electrically conductive structures 128 and pad regions of package layers 116 and 114.

Solder 130 may be disposed on the backside of light-emitting die 120, as illustrated in the cross-section view of FIG. 6. A reflow process may be used to attach the solder to adjacent surfaces, as known by those of skill in the art. In some embodiments, the reflow process is performed at temperatures ranging from about 180 degrees Celsius to about 280 degrees Celsius. In some embodiments, solder may be dispensed onto desired regions via a print process, such as screen printing. In some embodiments, solder may be deposited (e.g., vapor deposited) on the backside of the light-emitting die. Such a process may be performed at the wafer-level prior to dicing the dies, or after dicing. In some embodiments, the backside of the light-emitting die is free of solder, and may include an exposed gold-containing (e.g., gold or gold-alloy layer) surface.

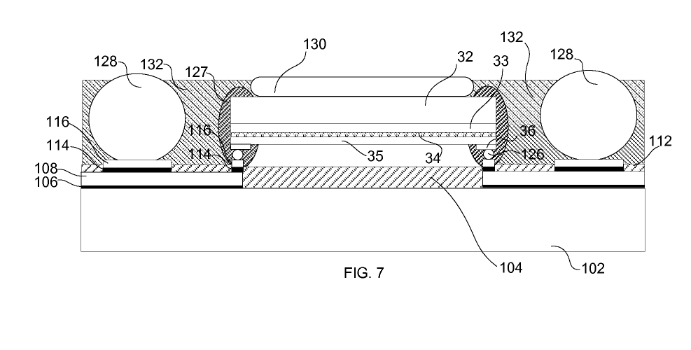

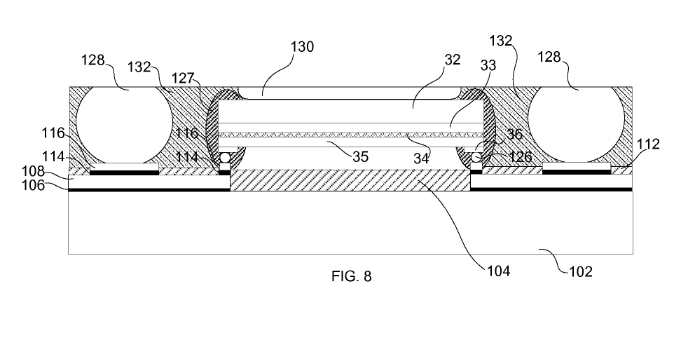

Filler material 132 may then be dispensed around the light-emitting die 120 and the electrically conductive structures 128, as illustrated in the cross-section view of FIG. 7. Providing (e.g., dispensing) the filler material 132 around the protective coating 127 (e.g., that seal of the light-emitting die) can form at least part of the package for the light-emitting die 120. Filler material 132 may be needle dispensed in regions around the light-emitting die 120 and electrically conductive structures 128. In some embodiments, filler material 132 may be deposited over the light-emitting die 120 (e.g., over solder 130) and/or over electrically conductive structures 128. Filler material 132 may be a low viscosity material (e.g., low viscosity epoxy) that self levels. In such a process, the protective coating 127 prevents filler material 132 from flowing onto the emission surface of the light-emitting die 120. After dispensing, a cure step may be performed to set the filler material. The cure step may include the application of heat and/or UV radiation. Grinding may then be performed so as to level the electrically conductive structures 128, filler material 132 and solder 130, as illustrated in the cross-section view of FIG. 8.

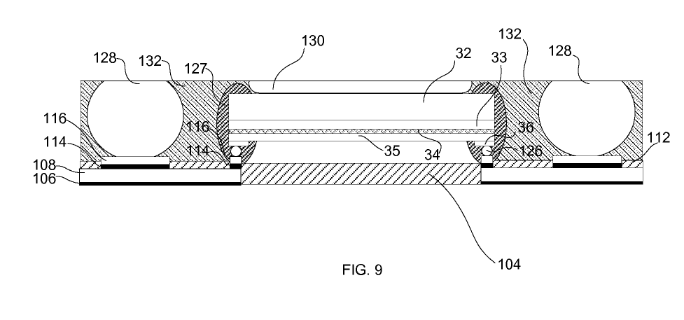

Substrate 102 can be removed, as illustrated in the cross-section view of FIG. 9. A selective etch may be used to remove substrate 102 and stop on layer 106. For example, when substrate 102 is formed of copper and layer 102 is nickel a selective etch including sulfuric acid may be used, as know by those of skill in the art.

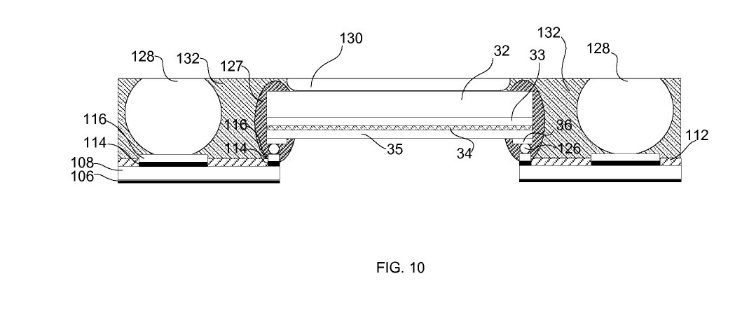

Mask material 104 may then be removed, resulting in a packaged device as illustrated in the cross-section view of FIG. 10. Removal of mask material 104 may be performed by the use of a selective etch and/or by the application and removal of an adhesive sheet that removes the mask material 104. In some embodiments, the selective etch is a water etch and the mask material is water soluble whereas protective coating 127 and filler material 132 can be water insoluble.

In some embodiments, the above process may be performed on an array of light-emitting devices formed from a common starting substrate. In some embodiments, the common starting substrate may have one or more edges greater than about 5 cm (e.g., greater than about 10 cm, greater than about 15 cm). The common starting substrate may have any suitable shape, for example a rectangular shape. A plurality of light-emitting dies may be attached to different regions of the common substrate, for example in an array configuration. In some embodiments, a common substrate can support at least about 50 (e.g., at least about 100, at least about 150, at least about 200) light-emitting dies. The light-emitting dies can then be packaged, as described above. At the end of the package assembly process, individual light-emitting devices may be separated by dicing the array of light-emitting devices (e.g., using a diamond saw, laser, or scribe/break) formed on the common substrate.

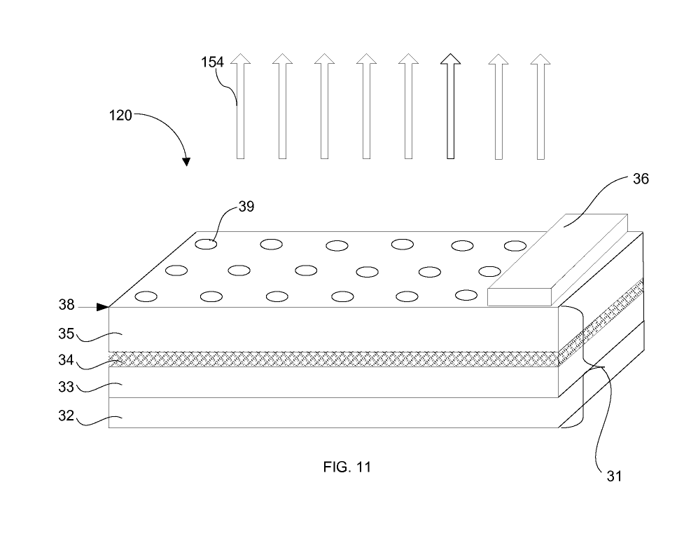

FIG. 11 illustrates a light-emitting diode (LED) which may be one example of a light-emitting die, in accordance with one embodiment. It should be understood that various embodiments presented herein can also be applied to other light-emitting dies, such as laser diode dies, and LED dies having different structures (such as organic LEDs, also referred to as OLEDs). LED die 120 shown in FIG. 11 comprises a multi-layer stack 31 that may be disposed on a support structure (not shown). The multi-layer stack 31 can include an active region 34 which is formed between n-doped layer(s) 35 and p-doped layer(s) 33. The stack can also include an electrically conductive layer 32 which may serve as a p-side contact, which can also serve as an optically reflective layer. An n-side contact pad 36 may be disposed on layer 35. Electrically conductive fingers (not shown) may extend from the contact pad 36 and along the surface 38, thereby allowing for uniform current injection into the LED structure.

It should be appreciated that the LED is not limited to the configuration shown in FIG. 11, for example, the n-doped and p-doped sides may be interchanged so as to form a LED having a p-doped region in contact with the contact pad 36 and an n-doped region in contact with layer 32. As described further below, electrical potential may be applied to the contact pads which can result in light generation within active region 34 and emission (represented by arrows 154) of at least some of the light generated through an emission surface 38. As described further below, holes 39 may be defined in an emission surface to form a pattern that can influence light emission characteristics, such as light extraction and/or light collimation. It should be understood that other modifications can be made to the representative LED structure presented, and that embodiments are not limited in this respect.

The active region of an LED can include one or more quantum wells surrounded by barrier layers. The quantum well structure may be defined by a semiconductor material layer (e.g., in a single quantum well), or more than one semiconductor material layers (e.g., in multiple quantum wells), with a smaller electronic band gap as compared to the barrier layers. Suitable semiconductor material layers for the quantum well structures can include InGaN, AlGaN, GaN and combinations of these layers (e.g., alternating InGaN/GaN layers, where a GaN layer serves as a barrier layer). In general, LEDs can include an active region comprising one or more semiconductors materials, including III-V semiconductors (e.g., GaAs, AlGaAs, AlGaP, GaP, GaAsP, InGaAs, InAs, InP, GaN, InGaN, InGaAlP, AlGaN, as well as combinations and alloys thereof), II-VI semiconductors (e.g., ZnSe, CdSe, ZnCdSe, ZnTe, ZnTeSe, ZnS, ZnSSe, as well as combinations and alloys thereof), and/or other semiconductors. Other light-emitting materials are possible such as quantum dots or organic light-emission layers.

The n-doped layer(s) 35 can include a silicon-doped GaN layer (e.g., having a thickness of about 4000 nm thick) and/or the p-doped layer(s) 33 include a magnesium-doped GaN layer (e.g., having a thickness of about 40 nm thick). The electrically conductive layer 32 may be a silver layer (e.g., having a thickness of about 100 nm), which may also serve as a reflective layer (e.g., that reflects upwards any downward propagating light generated by the active region 34). Furthermore, although not shown, other layers may also be included in the LED; for example, an AlGaN layer may be disposed between the active region 34 and the p-doped layer(s) 33. It should be understood that compositions other than those described herein may also be suitable for the layers of the LED.

As a result of holes 39, the LED can have a dielectric function that varies spatially according to a pattern. Typical hole sizes can be less than about one micron (e.g., less than about 750 nm, less than about 500 nm, less than about 250 nm) and typical nearest neighbor distances between holes can be less than about one micron (e.g., less than about 750 nm, less than about 500 nm, less than about 250 nm). Furthermore, as illustrated in the figure, the holes 39 can be non-concentric.

The dielectric function that varies spatially according to a pattern can influence the extraction efficiency and/or collimation of light emitted by the LED. In some embodiments, a layer of the LED may have a dielectric function that varies spatially according to a pattern. In the illustrative LED die 120 of FIG. 11, the pattern is formed of holes, but it should be appreciated that the variation of the dielectric function at an interface need not necessarily result from holes. Any suitable way of producing a variation in dielectric function according to a pattern may be used. For example, the pattern may be formed by varying the composition of layer 35 and/or emission surface 38. The pattern may be periodic (e.g., having a simple repeat cell, or having a complex repeat super-cell), or non-periodic. As referred to herein, a complex periodic pattern is a pattern that has more than one feature in each unit cell that repeats in a periodic fashion. Examples of complex periodic patterns include honeycomb patterns, honeycomb base patterns, (2×2) base patterns, ring patterns, and Archimedean patterns. In some embodiments, a complex periodic pattern can have certain holes with one diameter and other holes with a smaller diameter. As referred to herein, a non-periodic pattern is a pattern that has no translational symmetry over a unit cell that has a length that is at least 50 times the peak wavelength of light generated by one or more light-generating portions. As used herein, peak wavelength refers to the wavelength having a maximum light intensity, for example, as measured using a spectroradiometer. Examples of non-periodic patterns include aperiodic patterns, quasi-crystalline patterns (e.g., quasi-crystal patterns having 8-fold symmetry), Robinson patterns, and Amman patterns. A non-periodic pattern can also include a detuned pattern (as described in U.S. Pat. No. 6,831,302 by Erchak, et al., which is incorporated herein by reference in its entirety). In some embodiments, a device may include a roughened surface. The surface roughness may have, for example, a root-mean-square (rms) roughness about equal to an average feature size which may be related to the wavelength of the emitted light.

In certain embodiments, an interface of a light-emitting device is patterned with holes which can form a photonic lattice. Suitable LEDs having a dielectric function that varies spatially (e.g., a photonic lattice) have been described in, for example, U.S. Pat. No. 6,831,302 B2, entitled “Light emitting devices with improved extraction efficiency,” filed on Nov. 26, 2003, which is herein incorporated by reference in its entirety. A high extraction efficiency for an LED implies a high power of the emitted light and hence high brightness which may be desirable in various optical systems.

It should also be understood that other patterns are also possible, including a pattern that conforms to a transformation of a precursor pattern according to a mathematical function, including, but not limited to an angular displacement transformation. The pattern may also include a portion of a transformed pattern, including, but not limited to, a pattern that conforms to an angular displacement transformation. The pattern can also include regions having patterns that are related to each other by a rotation. A variety of such patterns are described in U.S. Patent Publication No. 20070085098, entitled “Patterned devices and related methods,” filed on Mar. 7, 2006, which is herein incorporated by reference in its entirety.

Light may be generated by the LED as follows. The p-side contact layer can be held at a positive potential relative to the n-side contact pad, which causes electrical current to be injected into the LED. As the electrical current passes through the active region, electrons from n-doped layer(s) can combine in the active region with holes from p-doped layer(s), which can cause the active region to generate light. The active region can contain a multitude of point dipole radiation sources that generate light with a spectrum of wavelengths characteristic of the material from which the active region is formed. For InGaN/GaN quantum wells, the spectrum of wavelengths of light generated by the light-generating region can have a peak wavelength of about 445 nanometers (nm) and a full width at half maximum (FWHM) of about 30 nm, which is perceived by human eyes as blue light. The light emitted by the LED may be influenced by any patterned surface through which light passes, whereby the pattern can be arranged so as to influence light extraction and/or collimation.

In other embodiments, the active region can generate light having a peak wavelength corresponding to ultraviolet light (e.g., having a peak wavelength of about 370-390 nm), violet light (e.g., having a peak wavelength of about 390-430 nm), blue light (e.g., having a peak wavelength of about 430-480 nm), cyan light (e.g., having a peak wavelength of about 480-500 nm), green light (e.g., having a peak wavelength of about 500 to 550 nm), yellow-green (e.g., having a peak wavelength of about 550-575 nm), yellow light (e.g., having a peak wavelength of about 575-595 nm), amber light (e.g., having a peak wavelength of about 595-605 nm), orange light (e.g., having a peak wavelength of about 605-620 nm), red light (e.g., having a peak wavelength of about 620-700 nm), and/or infrared light (e.g., having a peak wavelength of about 700-1200 nm).

In certain embodiments, the LED may emit light having a high light output power. As previously described, the high power of emitted light may be a result of a pattern that influences the light extraction efficiency of the LED. For example, the light emitted by the LED may have a total power greater than 0.5 Watts (e.g., greater than 1 Watt, greater than 5 Watts, or greater than 10 Watts). In some embodiments, the light generated has a total power of less than 100 Watts, though this should not be construed as a limitation of all embodiments. The total power of the light emitted from an LED can be measured by using an integrating sphere equipped with spectrometer, for example a SLM12 from Sphere Optics Lab Systems. The desired power depends, in part, on the optical system that the LED is being utilized within. For example, a display system (e.g., a LCD system) may benefit from the incorporation of high brightness LEDs which can reduce the total number of LEDs that are used to illuminate the display system.

The light generated by the LED may also have a high total power flux. As used herein, the term “total power flux” refers to the total optical power divided by the emission area. In some embodiments, the total power flux is greater than 0.03 Watts/mm², greater than 0.05 Watts/mm², greater than 0.1 Watts/mm², or greater than 0.2 Watts/mm². However, it should be understood that the LEDs used in systems and methods presented herein are not limited to the above-described power and power flux values.

In some embodiments, the LED may be associated with one or more wavelength converting regions. The wavelength converting region(s) may include one or more phosphors and/or quantum dots. The wavelength converting region(s) can absorb light emitted by the light-generating region of the LED and emit light having a different wavelength than that absorbed. In this manner, LEDs can emit light of wavelength(s) (and, thus, color) that may not be readily obtainable from LEDs that do not include wavelength converting regions. In some embodiments, one or more wavelength converting regions may be disposed over (e.g., directly on) the emission surface (e.g., surface 38) of the light-emitting device.

As used herein, when a structure (e.g., layer, region) is referred to as being “on”, “over” “overlying” or “supported by” another structure, it can be directly on the structure, or an intervening structure (e.g., layer, region) also may be present. A structure that is “directly on” or “in contact with” another structure means that no intervening structure is present.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A light-emitting device comprising:
a light-emitting die comprising a light-generating region capable of generating light and an emission surface through which generated light is capable of being emitted; and
a package layer at least partially disposed over at least a portion of the light-emitting die emission surface, wherein the package layer has an aperture through which light from the light-emitting die is capable of being emitted.

2. The device of claim 1, wherein the package layer includes an electrically conductive material that forms an electrical connection with the light-emitting die.

3. The device of claim 2, wherein the electrically conductive material serves as at least part of a first electrical contact path to the light-emitting die.

4. The device of claim 3, wherein the light-emitting die includes an electrical bond pad disposed over the emission surface, and wherein the electrically conductive material is in electrical connection with the electrical bond pad.

5. The device of claim 3, wherein a backside of the light-emitting die serves as at least part of a second electrical contact path to the light-emitting die.

6. The device of claim 5, wherein the light-emitting die includes a p-type side and an n-type side, and wherein the first electrical contact path connects to the n-type side of the light-emitting die, and wherein the second electrical contact path connects to the p-type side of the light-emitting die.

7. The device of claim 2, further including an electrically conductive path from the electrically conductive material to a backside of the device.

8. The device of claim 7, wherein the electrically conductive path comprises at least one solder ball, at least one metal ball, at least one metal column, or at least one lead.

9. The device of claim 1, wherein a backside of the light-emitting die is at least partially covered by solder.

10. The device of claim 1, wherein the aperture has a substantially different shape than the light-emitting die.

11. The device of claim 1, wherein the light-emitting die emission surface area is greater than or equal to 3 mm².

12. The device of claim 1, wherein the light-emitting die emission surface area is greater than or equal to 10 mm².

13. The device of claim 1, wherein the device area is less than 3 times the light-emitting die emission surface area.

14. The device of claim 1, wherein the device area is less than 1.5 times the light-emitting die emission surface area.

15. The device of claim 1, wherein the device thickness is less than 2 times the light-emitting die thickness.

16. The device of claim 1, wherein the device thickness is less than 1.5 times the light-emitting die thickness.

17. The device of claim 1, wherein the device thickness is less than 500 micrometers.

18. The device of claim 1, wherein a top surface of the package layer is less than 100 micrometers from the light-emitting die emission surface.

19. The device of claim 1, wherein the light-emitting die comprises one or more light extraction features.

20. The device of claim 19, wherein the one or more light extraction features comprise a roughed surface.

21. The device of claim 19, wherein the one or more light extraction features comprise a surface having dielectric function that varies spatially according to a pattern.

22. A light-emitting device comprising:
a light-emitting die comprising a light-generating region capable of generating light and an emission surface through which generated light is capable of being emitted; and
a package that houses the light-emitting die, wherein the light-emitting die is at least partially embedded in the package, and
wherein the device area is less than 3 times the light-emitting die emission surface area.

23. A light-emitting device comprising:
a light-emitting die comprising a light-generating region capable of generating light and an emission surface through which generated light is capable of being emitted; and
a package that houses the light-emitting die, wherein the light-emitting die is at least partially embedded in the package, and
wherein the device thickness is less than 2 times the light-emitting die thickness.

24. A light-emitting device comprising:
a light-emitting die comprising a light-generating region capable of generating light and an emission surface through which generated light is capable of being emitted; and
a package that houses the light-emitting die, the package having a top surface less than 100 micrometers from the light-emitting die emission surface.

25. A method of making a light-emitting device, the method comprising:
providing a light-emitting die comprising a light-generating region capable of generating light and an emission surface through which generated light is capable of being emitted; and
providing a package layer at least partially disposed over at least a portion of the light-emitting die emission surface, wherein the package layer has an aperture through which light from the light-emitting die is capable of being emitted.
